(19) United States
(12) Patent Application Publication
(10) Pub. No.: US 2025/0390028 A1
(43) Pub. Date: Dec. 25, 2025

(54) SYSTEMS AND METHODS FOR OPTICAL MEASURING OF PROPERTIES OF SAMPLES USING POLARIZED OPTICAL BEAMS

(71) Applicant: NOVA LTD., Rehovot (IL)

(72) Inventors: Shimon YALOV, Rehovot (IL); Misha Matusovsky, Rehovot (IL); Eyal COHEN, Rehovot (IL); Shachar PAZ, Rehovot (IL)

(73) Assignee: NOVA LTD., Rehovot (IL)

(21) Appl. No.: 18/879,245

(22) PCT Filed: Dec. 27, 2022
(86) PCT No.: PCT/IL2022/051392

§ 371 Date: Dec. 26, 2024

(30) Foreign Application Priority Data
Jun. 30, 2022 (IL) 294457

(51) Int. Cl. G03F 7/00

(52) U.S. Cl. CPC G03F 7/706849; G03F 7/7055; G03F 7/706851

(57) ABSTRACT

Systems and methods are provided for measuring properties of a sample such as a semiconductor element by illuminating a polarizing beam splitter (PBS) with spatially separated non-polarized input optical beams such that the PBS polarizes the input optical beams to produce at least two polarized intermediate optical beams having different (e.g., orthogonal) polarization properties. The polarized intermediate optical beams are further directed to illuminate substantially the same area of a sample. Light returned from the illuminated sample area is directed again through the same PBS to form at least two polarized output beams, having different (e.g., orthogonal) polarization properties, where the differently polarized output optical beams are detectable by use of one or more optical detectors. In some embodiments, the sample is simultaneously illuminated by combined intermediate polarized optical beams of different polarization properties and the polarized output optical beams are also simultaneously measured by the optical detector(s).

The present disclosure relates in general to systems and methods for optical measuring of properties of samples such as semiconductors (wafers) and more particularly to metrology using polarized optical beams.

### BACKGROUND

Metrology and inspection of semiconductor elements such as wafers in semiconductor manufacturing requires constant precision improvement for adapting to smaller and smaller wafer features geometry. Optical scatterometry or so-called optical critical dimension (OCD) metrology is often used for in-line optical measuring of various physical characteristics of the semiconductor (wafer) sample e.g., the feature dimensions such as line-width, height, side-wall angle, rounding, etc. of the patterned micro/nano structures.

Integrated or in-line metrology systems, that are integrated with wafer processing tool/device/machinery such as systems described in WO2020105036, which is incorporated herein by reference in its entirety,, or an integrated wafer polisher such as a chemical mechanical polishing (CMP) device, require even more demanding features than standard standalone metrology systems. One of such requirements is a high throughput of integrated metrology systems which should be compatible with the throughput of semiconductor processing equipment. Another requirement is a limited volume/footprint for the metrology system/device, which could take only predetermined limited part of overall semiconductor equipment.

These measuring/inspection techniques introduce additional challenges in terms of costs, equipment space and throughput time.

### BRIEF DESCRIPTION OF THE FIGURES

The figures illustrate generally, by way of example, but not by way of limitation, various embodiments discussed in the present document.

For simplicity and clarity of illustration, elements shown in the figures have not necessarily been drawn to scale. For example, the dimensions of some of the elements may be exaggerated relative to other elements for clarity of presentation. Furthermore, reference numerals may be repeated among the figures to indicate corresponding or analogous elements. References to previously presented elements are implied without necessarily further citing the drawing or description in which they appear. The figures are listed below.

FIG. 1 shows an optical head including an objective and polarizing beam splitter (PBS). PBS combines two polarized beams having orthogonal polarization to provide an overlapped illumination spots on the tested sample. The same PBS spits the reflected beam from the sample, into two beams with different polarization followed by their feeding to the corresponding detectors.

FIG. 2 shows a schematic illustration of an optical system for measuring samples' properties, using a single polarizing beam splitter (PBS), according to some embodiments.

FIGS. 3A and 3B show two optional arrangements of an optical system for measuring properties of samples, using a single PBS for simultaneous splitting and polarizing of light emanating from a single light source and measuring of returned light reflected/scattered from a sample, using two separate detection units, also using a separate sample inspection subsystem that can separately measure sample properties using a different measuring technique, according to some embodiments: FIG. 3A shows a first arrangement of the system, and FIG. 3B shows a second arrangement of the system.

FIG. 4 shows an optical system for measuring properties of samples, using a single bifurcated collection optical fiber for simultaneous measuring of P-type and S-type polarized beams, according to some embodiments.

FIG. 5 is a flowchart, schematically illustrating at least main steps of a method for measuring sample's properties by using polarized optical beams and single PBS, according to some embodiments.

### SUMMARY OF EMBODIMENTS OF THE INVENTION

Aspects of disclosed embodiments pertain to an optical system for measuring properties of a sample, the optical system comprising at least:
an optical head comprising at least a polarizing beam splitter (PBS);
an illumination subsystem comprising at least: a light source, a light splitting element configured to separate an initial optical beam emanating from said light source into at least two spatially separated non-polarized input optical beams;
a first optical setup comprising one or more optical elements configured at least to direct each of said input optical beams into the PBS, wherein the PBS is located and configured to polarize the input optical beams to produce at least two polarized intermediate optical beams having different polarization properties, wherein the intermediate optical are directed to illuminate substantially the same area of a sample to be measured, wherein the PBS is further used to split light returned from the sample, to form at least two polarized output beams, having different polarization properties; and
a detection subsystem having at least one optical detector, configured to separately detect each of the output optical beams, returned from the sample.

Other aspects of disclosed embodiments pertain to a method for measuring properties of a sample, the method comprising at least:
providing at least one light source outputting an initial optical beam, which is non-polarized;
splitting the initial optical beam into two or more non-polarized spatially separated input optical beams;
directing each of the input optical beams through a polarizing beam splitter (PBS) for producing at least two polarized intermediate optical beams having different polarization properties, using a first optical setup;
directing the at least two polarized intermediate optical beams such as to illuminate at least one area of a respective sample;
directing light returned from the sample through the same PBS, to form at least two polarized output beams, having different polarization properties; and
separately detecting each of the output optical beams, returned from the sample, using at least one optical detector to determine one or more physical properties of the respective sample.

The above system and method may be used for a standalone metrology or for integrated inline metrology of samples e.g., for improving metrology performances, quality, and/or throughput speed.

### DETAILED DESCRIPTION

Some embodiments of the disclosed invention pertain to systems and methods for samples' metrology/scatterometry for determining one or more physical properties of a sample being inspected or at least area/part thereof, by illumination of each sample/sample area with polarized optical beams.

The terms “beam(s)” and “optical beams” may be used interchangeably herein.

Aspects of disclosed embodiments pertain to an optical system for measuring properties of a sample, the optical system may include at least:
(i) an optical head comprising at least a polarizing beam splitter (PBS);
(ii) an illumination subsystem which may be configured to generate two or more non-polarized spatially separated input optical beams e.g., by using an optical beam splitter to split an initial optical beam emanating from a single light source into at least two spatially separated non-polarized input optical beams or by use of two or more light sources, and optionally also at least one optical setup comprising one or more optical elements and/or devices, configured to direct each of the non-polarized spatially separated input optical beams into the PBS; and
(iii) a detection subsystem including one or more optical detectors such as one or more spectrometers, one or more pixelated optical detectors/cameras, etc. for detection of one or more properties such as spectral related properties of the sample of the area(s) thereof (e.g., polarized spectral reflection).

According to some embodiments, the PBS is located and configured to simultaneously polarize the non-polarized and spatially separated input optical beams to simultaneously produce at least two polarized intermediate optical beams having different (e.g., orthogonal) polarization properties, and further simultaneously direct the intermediate optical beams such as to simultaneously illuminate substantially the same area of a sample to be measured. The PBS may further be used to split and polarize light returned from the sample, such as to form at least two polarized output beams, having different polarization properties, outputted from at least one surface of the PBS.

According to some embodiments, the one or more optical detectors of the detection subsystem may be configured and located to separately, and optionally simultaneously detect optical properties of each of the output optical beams directly outputted from the PBS, or manipulated output beams generated by having one or more of the polarized output optical beams through one or more elements modifying/changing some of the original properties of the polarized output beams returned from the sample and outputted from the PBS.

According to some embodiments, the data/signals from each optical detector can then be used to determine one or more properties of the sample or a part/area/spot of the sample that is being illuminated.

According to some embodiments, the polarized intermediate optical beams and/or the polarized output optical beams, formed by the PBS, have orthogonal polarizations such as, yet not limited to P and S polarizations.

According to some embodiments, the spatially separated and non-polarized input optical beams may be directed (e.g., by one or more elements of the first optical setup) onto different input surfaces of the PBS that are angular (e.g., perpendicular) to one another. In this case the PBS may be configured to receive the non-polarized input optical beams from different angularly positioned surfaces thereof and output two orthogonally polarized intermediate optical beams that are propagated at the same propagation direction (e.g., by combining the input optical beams and/or by outputting parallel differently polarized intermediate optical beams).

The combined/parallel polarized intermediate optical beams are directed such as to impinge an area of a sample positioned in their optical path such as to have the combined intermediate optical beams illuminate the sample area. Light from the illuminated sample area is then scattered/reflected from the sample and directed back to the same PBS to be polarized again thereby, outputting corresponding two or more polarized output optical beams that are then collected by the detection subsystem for being measured thereby.

According to some embodiments, the optical system for polarization-based metrology of samples may be used as an integrated metrology (IM) system, e.g., by being embedded in or attached to a semiconductor processing/manufacturing system, enabling fast and high quality/accuracy efficient samples inspection that is integrated with the entire wafer/sample processing and/or production. For improved IM, the optical system, using a single PBS, maybe designed to be as compact as possible without affecting metrology quality and/or throughput performances of the processing system.

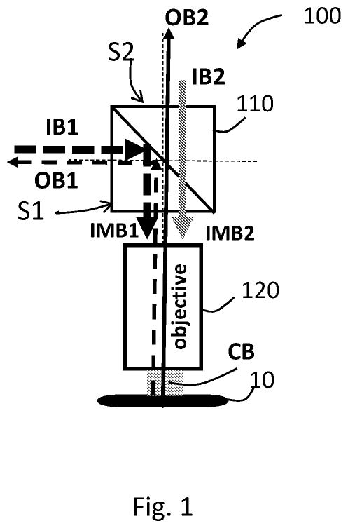

FIG. 1A shows a polarization unit 100 for measuring properties of a sample 10 or an area(s) thereof, according to some embodiments. The polarization unit 100 including, for example: a PBS 110 and optionally one or more optical elements such as an objective 120.

The PBS 110 is positioned and configured to simultaneously polarize two non-polarized and spatially separated input optical beams IB1 and IB2 each impinging/entering the PBS 110 from a different surface thereof such as perpendicular input surfaces S1 and S2, respectively, such as to form two orthogonally S and P polarized co-aligned optical beams IMB1 and IMB2. The co-aligned optical beams IMB1 and IMB2 are focused by the objective 120 to form overlapped illumination spots on the sample.

The illumination beams IMB1 and IMB2 are reflected/scattered by the sample 10. The reflected/scattered light passes through the same PBS 110 again and is therefore polarized by the PBS 110 again, generating/outputting polarized output optical beams OB1 and OB2 (SEE FIG. 1) that may exit different surfaces of PBS 110 that are angular to one another (forming a non-zero angle therebetween).

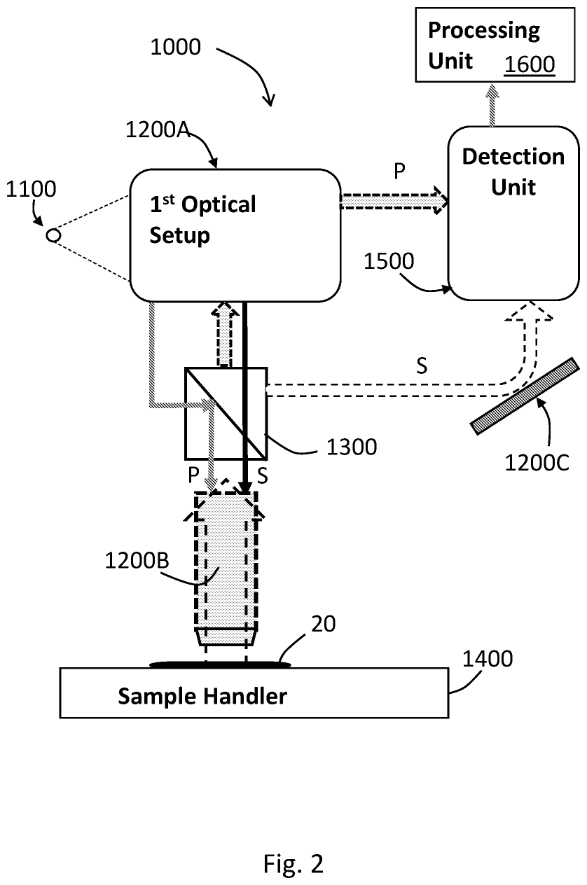

Reference is now made to FIG. 2, showing an optical system 1000 for optically measuring samples such as sample 20, according to some embodiments. The optical system 1000 may generally include:
a single light source 1100;
a first optical setup 1200A;
a second optical setup 1200B;
a PBS 1300; and
a third optical setup 1200C;
(optionally) a sample handler 1400;
a detection unit 1500; and
a processing unit 1600.

According to some embodiments, the first optical setup 1200A may include one or more optical elements/devices configured and positioned to receive light emanating from the light source 1100, generate two or more spatially separated and non-polarized input optical beams and direct the input optical beams to imping one or more surfaces of the PBS 1300 (such as two different PBS 1300 (angular) surfaces in this example shown in FIG. 2).

The PBS 1300 may be positioned and configured to polarize the incoming input optical beams such as to form two orthogonally polarized intermediate optical beams outputted through another surface thereof.

According to some embodiments, the second optical setup 1200B may include one or more optical elements/devices such as an objective, positioned and configured to direct the polarized intermediate optical beams outputted from the PBS 1300 towards the sample 20 or towards at least one particular area of the sample 20; and/or to combine and/or collect light of the co-aligned optical beams to form a dual image of the light source 1100 over an area of the sample 20.

According to some embodiments, the second optical setup 1200B may further be configured to direct returned light that is reflected/scattered from the sample 20 and direct it such that the returned light is passed through and polarized by the PBS 1300 again, forming two orthogonally polarized output optical beams, outputted through one or more surfaces of the PBS 1300 (e.g., through one or more of the surfaces through which the input and/or intermediate optical beam(s) pass) or through at least one completely different output surface.

According to some embodiments, the third optical setup 1200C may include one or more optical elements/devices such as one or more reflective/semi-reflective elements positioned and configured to direct the polarized output optical beams outputted from the PBS 1300, towards the detection subsystem 1500.

According to some embodiments, the detection subsystem 1500 may include one or more optical detectors, configured and positioned to simultaneously and separately measure spectral intensity at corresponding polarization of each of the output optical beams.

According to some embodiments, the output optical beams, outputted from the PBS 1300 may be manipulated in one manner or another before reaching the one or more optical detectors of the detection subsystem 1500, such as by being interfered with the input optical beams, by being further polarized or de-polarized, by being shaped, imaged, focused, or collimated etc. before reaching the detection subsystem, and the like.

It is noted that the term output optical beam(s) measured by the detection subsystem may refer in this document to interfered/manipulated output optical beam(s) (in cases in which the system is configured to have the output optical beams being manipulated before reaching the detection subsystem) or to optical beams outputted by the PBS and either directly detected by the detection subsystem or being directed by one or more directing optical elements such as reflectors, semi-reflectors, beam splitters etc., to the detection subsystem, depending on system configuration and requirements.

Output data or output signals, outputted by the one or more optical detectors of the detection subsystem 1500 may be collected by the processing unit 1600 for analysis/processing thereof, e.g., by using one or more software and/or hardware means/devices/modules to carry out the output signal/data processing.

According to some embodiments, the sample handler 1400 may be configured to hold one or more samples for measuring thereof. Optionally, the sample handler 1400 may also include controllable sample-handling means for example, for automatic conveying/displacing and/or positioning of each sample for placing and removing a sample from a stage of the sample handler 1400, for adjusting positioning of the sample to be measured to enable measuring one or more particular areas thereof, etc.

According to some embodiments, samples measured by the optical system 1000 may be semiconductor elements such as semiconductor wafers.

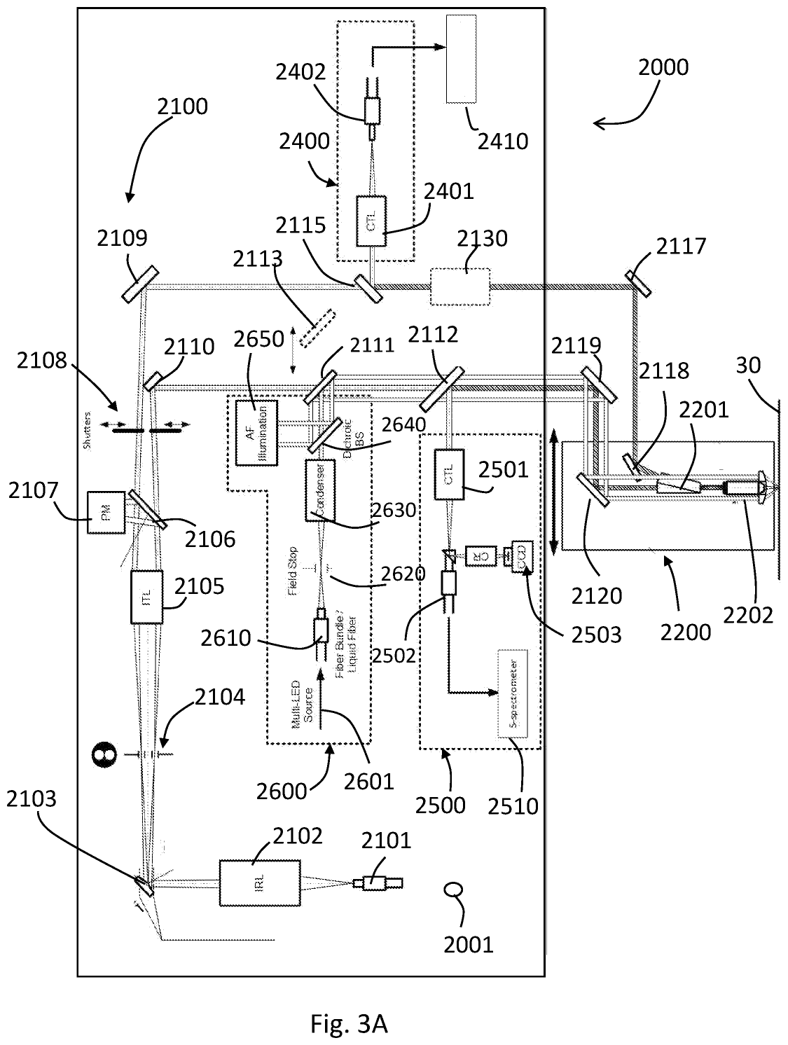

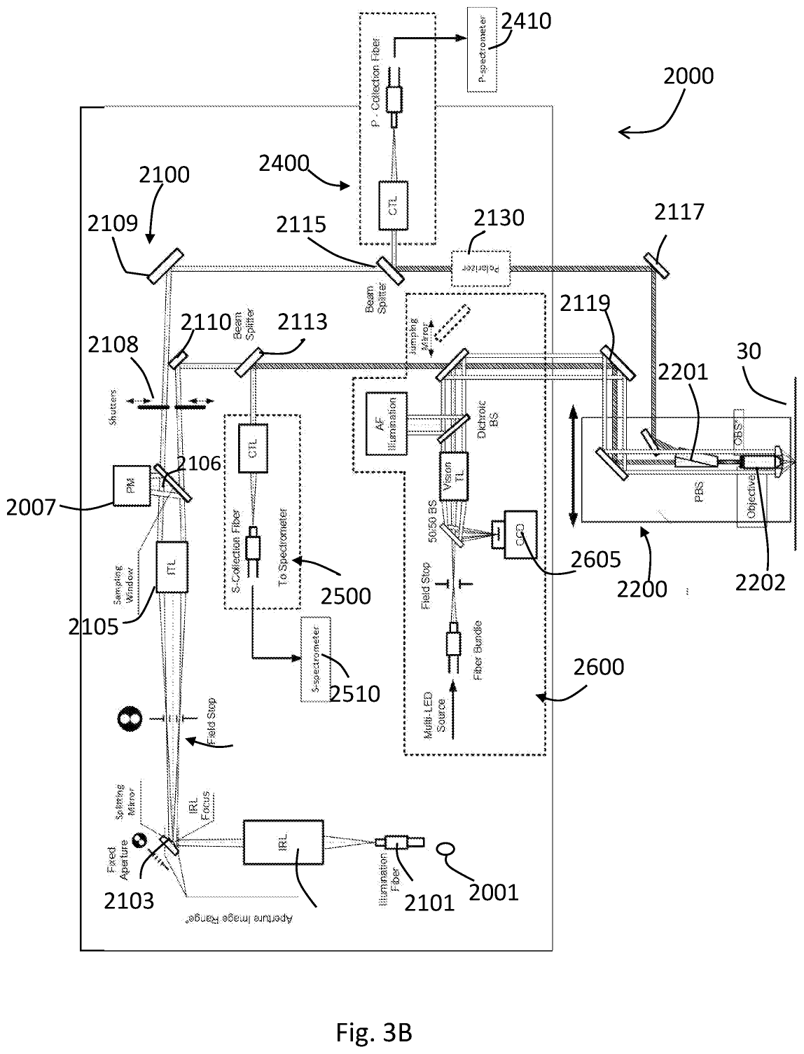

Reference is now made to FIGS. 3A and 3B schematically illustrating a system 2000 for optically measuring samples, according to some embodiments. The system 2000 may generally include:
a single light source 2001 having significant deep UV content to enable spectral measurements down to 190 nm e.g. Laser-Driven Light Sources (LDLS®, commercially available from Energetiq Technology);
an optical head 2200 including at least a PBS 2201 and an objective 2202;
a first optical setup 2100 configured mainly to convert light from the single light source 2001 to form two spatially separated non-polarized input optical beams and direct each of the input optical beams to the PBS 2201, which forms polarized intermediate optical beams for illuminating a sample 30, where light returned (reflected/scattered) by the sample passes through the PBS 2201 again, outputting two polarized output optical beams, where the first optical setup 2100 is further configured to direct each of the polarized output optical beams, outputted by the PBS 2201, towards a different optical detector of a detection subsystem of the system 2000;
a detection subsystem including, for example:
(i) a first optical collection and detection subsystem 2400 (e.g. for detecting output optical beams of a first polarization such as S-polarization) that includes: one or more optical elements for collecting and/or directing one of the polarized output optical beams such as a tube lens 2401 and a collection optical fiber 2402 and a first optical detector 2410 such as a spectrometer and
(ii) a second optical collection and detection subsystem 2500 (e.g. for detecting output optical beams of a second polarization such as P-polarization) that includes: one or more optical elements for collecting and/or directing one of the polarized output optical beams such as a tube lens 2501, a collection optical fiber 2502 and a second optical detector 2510 such as a spectrometer, where the second optical collection and detection subsystem 2500 may further include additional beam collection and detection means 2503 such as a beam splitter (BS) which splits the output optical beam in order to sample a portion thereof and another optical detector such as a CCD (charged coupled device) or CMOS camera, forming imaging channel that might be used for navigating/alignment purposes; and
(optionally) an additional subsystem 2600, configured for an auto-focusing (AF) and/or navigating (e.g., an image processing based subsystem) that might comprise one or more illuminating sources (like multi wavelengths multi-LED, broadband or monochromatic LED or laser), and light directing/focusing elements configured to separately illuminate the sample 30. For example, the CCD of subsystem 2500 could be used for acquiring an image that can be further processed and used for alignment/navigating/positioning and/or AF purposes (e.g., in which case requiring installment of one or more AF detector(s).

According to some embodiments, the objective 2202 of the optical head 2200 may be used to combine the two orthogonally polarized intermediate optical beams outputted from the PBS 2201, towards a same illumination spot (sample area) over the sample 30, which may be done also by use of one or more reflectors (mirrors) positioned in the optical path of the intermediate optical beams.

According to some embodiments, the tube lens 2401 and/or 2501 through which the output optical beams are passed before they are guided through the respective collection optical fiber 2402 and 2502, may be located and configured in respect to the objective 2202 to form an enlarged image of the returned light (spot) collectable by the respective collection optical fiber 2402/2502, corresponsive to a size (e.g. diameter) of a core of the respective fiber 2402/2502.

According to some embodiments, the additional subsystem 2600 may be configured for an auto-focusing and/or navigating (e.g., based on image processing), and may include:
at least one light source 2601 such as a multi-chromatic light source (e.g., multi-LED light source);
one or more optical fibers such as a fiber bundle or a so-called liquid fiber 2610 for guiding light from the at least one light source 2601 (which may be configured to generate light of least one specific wavelength or wavelength range(s));
one or more field stops such as field stop 2620 for limiting spatial beam expansion of light emanating from the fiber 2610 for controlling spot size of illumination spots eventually formed over the sample 30;
a condenser 2630 imaging light from the source 2601 to a pupil of the objective 2202 to provide a Koehler illumination scheme;
an autofocus (AF) illuminator 2650; and
a BS such as a dichroic BS 2640.

According to some embodiments, the optical head 2200 may be displaceable/moveable by using a controllable and optionally also automatically controllable displacement mechanism, for sample 30 scanning/measuring. The displacement mechanism (not shown) may be designed to displace the optical head 2200 along a single (e.g. X-) or two (X- and Y-) linear axis that is perpendicular to an optical axis defined by the propagation direction of the optical beams and/or along a plane that is perpendicular to the optical axis.

According to some embodiments, the first optical setup 2100 may include:
a collection optical fiber 2101 for guiding light emanating from the light source 2001;
an illumination relay lens (IRL) 2102;
a light splitting element such as a prism 2103 for splitting light that emanates from the light source 2001 (and passed through the optical fiber 2101 and through the IRL 2102) to separate it into two non-polarized spatially separated input optical beams;
beam stops 2104 for limiting spatial expansion of the generated input optical beams;
an illumination tube lens (ITL) 2105 configured and positioned to collimate and/or redirect image of each of the input optical beams passed through the field stops 2104, while the output beamlets are tilted (angular) in respect to one another.
(optionally) shutters 2108 for controllably preventing/limiting light of any of the input optical beams from being further passed through; and
various reflective, beam splitting and/or semi-reflective optical elements such as:
(i) BS 2106, which may be used for sampling a portion of each of the input optical beams to be inspected by a power monitoring subsystem including, for example, an additional optical detector 2007) (e.g., for light source and or input optical beams beam quality inspection); and
(ii) reflective or semi-reflective elements 2109-2120, positioned and configured to further direct the input optical beams towards the PBS 2201 and to direct differently polarized output optical beams exiting the PBS 2201 such that each detection subsystem 2400 and 2500 will receive only output optical beam of its corresponding polarization.

According to some embodiments, at least one of the properties being measured by the monitoring subsystem may include, for instance, variations in intensity/power of the input optical beams (such as variations in intensities of the light source over the spectral range) to enable normalization of the measured spectral intensity(ies) such as for calibration/normalization of spectral data outputted from the one or more optical detectors to improve detection accuracy. Spectral measurement of the power via a power monitoring subsystem (such as via detector 2007) may be used especially in cases in which the power/intensity variation of the light source 2001 are not uniform over the spectral range and when normalization by integration (integral value of the spectrum) does not provide accurate correction for each wavelength over the spectral range.

According to some embodiments, at least some of the optical elements such as reflective/partially reflective elements of the optical setup 2100 may serve to reflect light of both input/output optical beams depending on size of each optical element and distance (spatial separation) between the beams.

According to some embodiments, as shown in FIG. 3A, one or more of the reflective or partially reflective elements such as partially reflective element 2113 may be movable/displaceable to enable switching from working with the system 2000 in a measurement mode to pattern recognition mode where light from multi source Led source 2601 is directed to illuminate an area on the wafer around the measuring site 30. The illumination module 2600 for illumination of pattern on the sample 30 could be combined with auto focus illumination module 2650 to control the an accurate Z position (position in the direction perpendicular to the wafer plane)

According to some embodiments, the first optical setup 2100 may further include an additional polarizer 2130 to improve polarization purity in case the PBS 2201 cannot provide sufficient extinction ratio over whole spectral range.

FIGS. 3A and 3B show two different possible implementations for locating the additional subsystem 2600 and/or its corresponding optical elements/components' arrangements.

The advantage of the second arrangement, shown in FIG. 3B, is higher transmission for the vision channel of the additional subsystem 2600 as the light does is not passed twice through the BS 2111 through the metrology channel as in the first arrangement shown in FIG. 3A. A possible drawback may be that the second arrangement (FIG. 3B) does not enable direct imaging of the illumination spot on the vision channel camera 2605. That can affect the alignment process and monitoring capabilities for the optical path, although may be overvcome using other solutions such as at alignment jigs level.

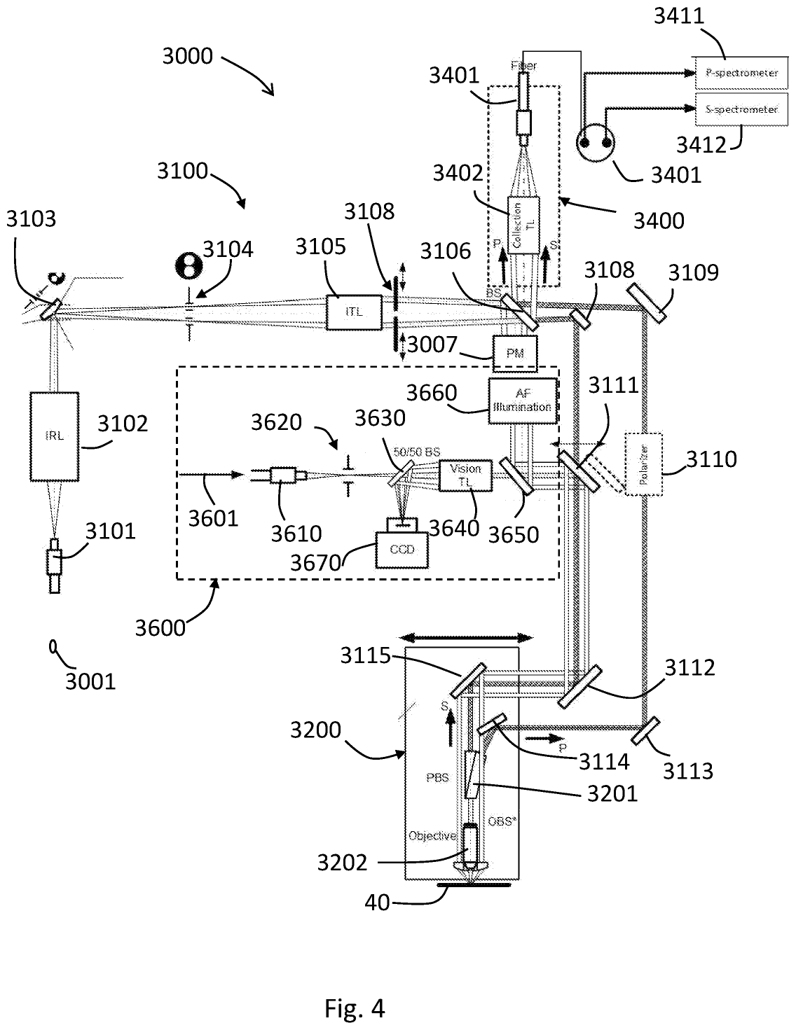

Reference is now made to FIG. 4 schematically showing a system 3000 for measuring samples properties, according to some embodiments.
a single light source 3001;
an optical head 3200 including at least a PBS 3201 and an objective 3202;
a first optical setup 3100 configured mainly to convert light from the single light source 3001 to form two spatially separated non-polarized input optical beams and direct each of the input optical beams to the PBS 3201 via the objective 3202, which forms polarized optical beams for illuminating a sample 40, where light returned (reflected/scattered) by the sample passes through the PBS 3201 again, outputting two polarized output optical beams, where the first optical setup 3100 is further configured to direct each of the polarized output optical beams, outputted by the PBS 3201, towards a different optical detector of a detection subsystem 3400 of the system 3000;
a detection subsystem including, a single optical collection and detection subsystem 3400 that includes: (i) one or more optical elements for collecting and/or directing and spatially separating each of the polarized output optical beams such as a tube lens 3402; (ii) a mutual collection optical fiber such as a bifurcated optical fiber 3401, enabling to simultaneously yet spatially differentiated images of each of the differently polarized output optical beams by channeling each output beam through different parts of the same fiber 3401; and (iii) one or more optical detectors such P-polarization channel spectrometer 3411 and S-polarization channel spectrometer 3412; and
(optionally) an additional subsystem 3600 configured to separately illuminate the sample 40 and detect returned light for optically measuring one or more properties of the sample 40.

According to some embodiments, the first optical setup 3100 may include:
an optical fiber 3101 for guiding light emanating from the light source 3001;
an illumination relay lens (IRL) 3102;
a light splitting element such as a prism 3103 for splitting light that emanates from the light source 3001 (and passed through the optical fiber 3101 and through the IRL 3102) to separate it into two non-polarized spatially separated input optical beams;
field stops 3104 for limiting spatial expansion of the generated input optical beams;
an ITL 3105 configured and positioned to collimate and/or redirect image of each of the input optical beams passed through the field stops 3104, e.g. such that the input optical beams that are outputted from an output surface of the ITL 3105 are not parallel to one another;
(optionally) shutters 3107/3108 for controllably preventing/limiting light of any of the input optical beams from being further passed through; and
various reflective, beam splitting and/or partially reflective optical elements such as:
(i) BS 3106, which may be used for sampling a portion of each of the input and/or output optical beams to be monitored (e.g., for light source and or input optical beams beam quality inspection) by using an additional optical detector 3007); and
(ii) reflective or partially reflective elements 3108-3115, positioned and configured to further direct the input optical beams towards the PBS 3201 and to direct differently polarized output optical beams exiting the PBS 3201 towards the detection subsystem 3400.

According to some embodiments, the use of a bifurcated optical fiber 3401 for simultaneous collection of both differently polarized output optical beams is done by having the ITL 3402 generating two image of the same measured area of the sample 40, each image being centered/focused at a different core of the bifurcated optical fiber 3401, where the fiber 3401 is connected such that it is able to feed each spectrometer 3411/3412 to an output optical beam of its corresponding polarization (e.g. S or P).

According to some embodiments, the additional subsystem 3600 may be configured for scanning the sample 40, and may include:
at least one light source 3601 such as a polychromatic light source (e.g., multi LED light source);
one or more optical fibers such as a finer bundle or a liquid fiber 3610 for guiding light from the at least one light source 3601, which may be configured to generate light of least one specific wavelength or wavelength range(s);
one or more field stops such as field stop 3620 for limiting spatial beam expansion of light emanating from the fiber 3610;
a BS 3630 for splitting the light emanating from the fiber 3610 and the light source 3601 to enable sampling a portion thereof/and or light returned from the sample 40 for optically detecting properties thereof via an additional optical detector 3670;
an autofocus (AF) illuminator 3660; and
one or more reflective or partially reflective elements such as reflective element 3650 for directing light from and to the optical head 3200.

According to some embodiments, one or more of the reflective or partially reflective elements such as partially reflective element 3113 may be movable/displaceable to enable switching from working with the system 3000 in a “polarization mode” in which the light source 3001 is used and the polarized output beams are directed to the detection subsystem 3400, to a “system operation inspection mode”, in which the additional subsystem 3600 is used for inspection of system functioning and operation quality, where inspection results can be used for improving/adjusting various system properties, devices, positioning thereof etc.

According to some embodiments, the samples being measurable by the system 3000 are semiconductor elements such as wafers.

According to some embodiments, the system 3000 design of FIG. 4, enables redirecting of the input/output optical beams into two illumination channels, by using a BS 3106 that takes portions of the unused energy of the optical beams to the power monitoring optical detector 3007 and the output optical beams, reflected from the sample 40, are reflected by the BS 3106 towards a mutual collection channel of the tube lens 3402, when there is some angle between them (i.g., while the output optical beams are not parallel to one another). which results in two images of the same measured sample 40 or illuminated spot thereover at two separated places, centered at the corresponding cores of the bifurcated optical fiber 3401.

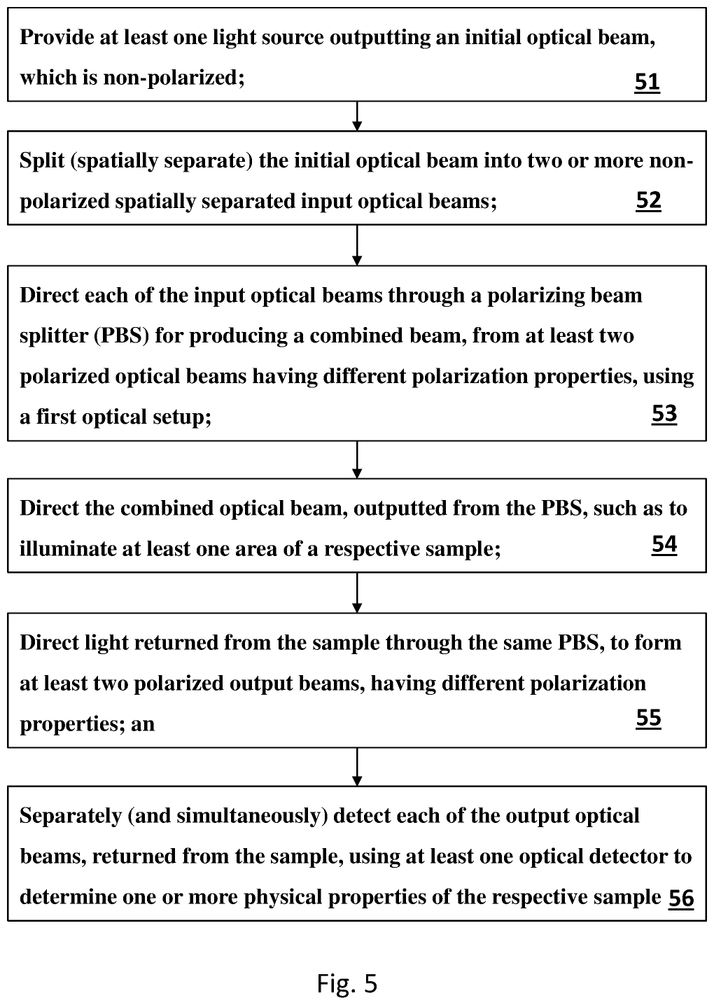

Reference is now made to FIG. 5, schematically showing a method for optically measuring properties of a sample. The method may include t least the following process steps:
providing at least one light source outputting an initial optical beam, which is non-polarized 51;
splitting the initial optical beam into two or more non-polarized spatially separated input optical beams 52;
directing each of the input optical beams through a polarizing beam splitter (PBS) for producing a combined optical beam from at least two polarized optical beams having different polarization properties, using a first optical setup 53;
directing the combined optical beam such as to illuminate at least one area of a respective sample 54;
directing light returned from the sample through the same PBS, to form at least two polarized output beams, having different polarization properties 55; and
separately detecting each of the output optical beams, returned from the sample, using at least one optical detector to determine one or more physical properties of the respective sample 56.

According to some embodiments, the method may also include: (i) receiving and processing data outputted from the at least one optical detector, using a processing unit and determining one or more physical properties of the respective sample being measured, based on processing of corresponding received data associated with detected returned light from the respective sample; and outputting information indicative of determined one or more physical characteristics of the respective sample.

According to some embodiments, the method may also include one of more of:
directing light from the at least one light source through an illumination relay lens (IRL);
splitting light outputted from the IRL into the two or more non-polarized and spatially separated input optical beams, using the light splitting element;
directing the input optical beams from the to the light splitting element towards two or more field stops, each positioned along an optical path of a different input optical beam and configured to limit the field of view (FOV) of each of the input optical beams emanating from the light splitting element;
collimating and/or guiding each of the input optical beams passed through the field stops while maintaining spatial separation therebetween, using one or more collimation and/or guiding elements; and
directing each of the input optical beams, emanating from the one or more collimating and/or guiding elements, such as to enter the PBS from a different surface of the PBS to form the at least two differently polarized optical beams further directed towards a test area over the respective sample.

According to some embodiments, the method may further include supporting achieving of a desired relative position between a test area of the respective sample and at least one light spot generated by the output optical beams illuminating the test area of the respective sample, using a navigation subsystem including, for example, a displacement mechanism for displacement or repositioning of the sample by displacement of an optical head including the PBS and/or displacement of a sample handler supporting/holding the sample to be measured.

According to some embodiments, the method may further include sampling a portion of each of the input optical beams and measuring one or more properties of the input optical beams to identify malfunctions in performances of the input optical beams, and perform corrections to identified malfunctions, using a monitoring subsystem.

### EXAMPLES

Example 1 is an optical system for measuring properties of a sample, the optical system comprising at least:
an optical head comprising at least a polarizing beam splitter (PBS);
an illumination subsystem comprising at least: a light source, a light splitting element configured to separate an initial optical beam emanating from said light source into at least two spatially separated non-polarized input optical beams;
a first optical setup comprising one or more optical elements configured at least to direct each of said input optical beams into the PBS, wherein the PBS is located and configured to polarize the input optical beams to produce at least two polarized intermediate optical beams having different polarization properties, wherein the intermediate optical are directed to illuminate substantially the same area of a sample to be measured, wherein the PBS is further used to split light returned from the sample, to form at least two polarized output beams, having different polarization properties; and
a detection subsystem having at least one optical detector, configured to separately detect each of the output optical beams, returned from the sample.

In example 2, the subject matter of example 1 may include, wherein the polarized at least two intermediate optical beams and/or at least two output optical beams formed by the PBS have orthogonal polarizations.

In example 3, the subject matter of any one or more of examples 1 to 2 may include, wherein the first optical setup is configured to direct each of the input optical beams onto different input surfaces of the PBS that are angular or perpendicular to one another.

In example 4, the subject matter of any one or more of examples 1 to 3 may include, wherein the optical setup may further include at least one additional polarizer.

In example 5, the subject matter of any one or more of examples 1 to 4 may include, wherein the at least two input optical beams have same or similar optical properties.

In example 6, the subject matter of any one or more of examples 1 to 5 may include, wherein the sample is simultaneously illuminated by the intermediate optical beams, for simultaneous measuring of the respective sample at two or more different polarizations.

In example 7, the subject matter of any one or more of examples 1 to 6 may include, wherein the light source is configured to output light of one of the following properties: white light; broadband light; light in the visual (VIS) wavelength (WL) range; light in the infrared (IR) WL range; light in the ultraviolet (UV) WL range.

In example 8, the subject matter of any one or more of examples 1 to 7 may include, wherein the first optical setup further comprises one or more of:
an illumination relay lens (IRL);
two or more field stops, each positioned along an optical path of a different input optical beam and configured to limit the field of view (FOV) of each of the input optical beams outputted from the light splitting element; and/or
a guiding unit comprising one or more beams collimating and/or guiding elements, for collimating and/or redirecting image of each of the input optical beams while maintaining spatial separation therebetween;
one or more reflective and/or semi-reflective elements for directing each of the input optical beams such as to enter the PBS from a different surface of the PBS.

In example 9, the subject matter of example 8 may include, wherein one or more of the reflective and/or semi-reflective elements of the first optical setup are controllably moveable.

In example 10, the subject matter of any one or more of examples 8 to 9 may include, wherein the first optical setup is further configured to generate at least two spatially separated images of the initial optical beam emanating from the light source.

In example 11, the subject matter of example 10 may include, wherein the guiding unit comprises an illumination tube lens (ITL), configured to collimate and/or redirect image of each of the input optical beams passed through the field stops.

In example 12, the subject matter of example 11 may include, wherein the input optical beams are outputted from a front surface of the ITL such that they are not parallel to one another.

In example 13, the subject matter of any one or more of examples 1 to 12 may include, wherein the detection subsystem comprises: at least two optical detectors, each configured and/or positioned to detect light of a different polarization property; and a second optical setup, which uses at least one of the optical elements of the first optical setup and/or additional optical elements, wherein the second optical setup is configured and arranged to direct each output optical beam to a different optical detector.

In example 14, the subject matter of example 13 may include, wherein at least one of the at least two optical detectors comprises a collection optical fiber.

In example 15, the subject matter of any one or more of examples 1 to 14 may include, wherein the optical head further comprises an objective located between a sample handler and the PBS.

In example 16, the subject matter of example 15 may include, wherein the optical head, the objective, and/or the sample is locatable such that the intermediate optical beams are combined and conjugated by the PBS and the objective to conjugate to a plane of the objective pupil that corresponds to a specific test area or central test area of the sample.

In example 17, the subject matter of any one or more of examples 1 to 16 may include, wherein the optical setup further includes a controllable displacement subsystem configured for moving of the optical head, a sample handler, and/or one or more parts of the sample handler.

In example 18, the subject matter of any one or more of examples 1 to 17 may include, wherein the BPS is configured for outputting intermediate and output optical beams of p-polarization and s-polarization.

In example 19, the subject matter of any one or more of examples 1 to 18 may include, wherein the at least one optical detector comprises at least one spectrometer.

In example 20, the subject matter of any one or more of examples 1 to 19 may include, wherein the optical setup further includes a monitoring subsystem configured and arranged to sample a portion of each of the input optical beams and measure variations in intensity/power of the input optical beams to enable correction of measured intensity/power variations.

In example 21, the subject matter of example 20 may include, wherein the monitoring subsystem comprises at least one additional detector; and at least one optical element configured and positioned to simultaneously direct a portion from each input optical beam towards the at least one additional detector.

In example 22, the subject matter of any one or more of examples 1 to 21 may include, wherein the optical setup further includes a processing unit configured to receive and process data outputted from the at least one optical detector, to determine one or more physical properties of each sample being measured.

In example 23, the subject matter of any one or more of examples 1 to 22 may include, wherein each sample being measured is a semiconductor wafer.

In example 24, the subject matter of any one or more of examples 1 to 23 may include, wherein the illumination subsystem further comprises a single optical fiber for outputting the initial light source to be split by the light splitting element; or two or more optical fibers each connectable to the light source and each being connected and configured to output a different input optical beam.

In example 25, the subject matter of example 24 may include, wherein the optical setup further include a navigation subsystem configured and arranged to support achieving of a desired relative position between a test area of the respective sample and at least one light spot generated by the output optical beams illuminating the test area of the respective sample.

In example 26, the subject matter of any one or more of examples 1 to 25 may include, wherein the first optical setup further comprises two or more shutters each positioned and configured to limit or prevent passage of a corresponding input optical beam.

In example 27, the subject matter of any one or more of examples 1 to 26 may include, wherein the optical setup further includes a sample inspection subsystem comprising at least one illuminator, a third optical setup and at least one optical sensor, the sample inspection subsystem being configured and positionable to measure physical properties of at least one test area of the respective sample by directing at least some of the light returned from the respective sample towards the at least one optical sensor.

In example 28, the subject matter of example 27 may include, wherein the sample inspection subsystem comprises a detachment mechanism for detaching from optical paths of the input and output optical beams to allow separate measurement of the same test area by illumination by the light source and use of the detection subsystem and by illumination by the illuminator and use of the at least one optical sensor.

In example 29, the subject matter of example 28 may include, wherein the detachment mechanism comprises a controllably movable reflector.

In example 30, the subject matter of any one or more of examples 27 to 29 may include, wherein the sample inspection subsystem comprises:
a first illuminator;
a second illuminator;
an optical sensor;
a third optical setup comprising optical elements that are positioned and configured to direct light emanating from the first and second illuminators towards the test area of the respective sample and light returned from the test area towards the optical sensor.

In example 31, the subject matter of any one or more of examples 27 to 30 may include, wherein the at least one optical sensor comprises one or more of: a camera, a pixelated optical sensor, a CCD camera, a spectrometer, an array of photo detectors.

Example 32 is a method for measuring properties of a sample, the method comprising at least:
providing at least one light source outputting an initial optical beam, which is non-polarized;
splitting the initial optical beam into two or more non-polarized spatially separated input optical beams;
directing each of the input optical beams through a polarizing beam splitter (PBS) for producing at least two polarized intermediate optical beams having different polarization properties, using a first optical setup;
directing the at least two polarized intermediate optical beams such as to illuminate at least one area of a respective sample;
directing light returned from the sample through the same PBS, to form at least two polarized output beams, having different polarization properties; and
separately detecting each of the output optical beams, returned from the sample, using at least one optical detector to determine one or more physical properties of the respective sample.

In example 33, the subject matter of example 32 may include, wherein the method may further include receiving and processing data outputted from the at least one optical detector, using a processing unit and determining one or more physical properties of the respective sample being measured, based on processing of corresponding received data associated with detected returned light from the respective sample.

In example 34, the subject matter of example 33 may include, wherein the method further includes outputting information indicative of determined one or more physical characteristics of the respective sample.

In example 35, the subject matter of any one or more of examples 32 to 34 may include, wherein the method further includes:
directing light from the light source through an illumination relay lens (IRL);
splitting light outputted from the IRL into the two or more non-polarized and spatially separated input optical beams, using the light splitting element;
directing the input optical beams from the to the light splitting element towards two or more field stops, each positioned along an optical path of a different input optical beam and configured to limit the field of view (FOV) of each of the input optical beams emanating from the light splitting element;
collimating and/or guiding each of the input optical beams passed through the field stops while maintaining spatial separation therebetween, using one or more collimation and/or guiding elements; and
directing each of the input optical beams, emanating from the one or more collimating and/or guiding elements, such as to enter the PBS from a different surface of the PBS to form the at least two differently polarized intermediate optical beams further directed towards a test area over the respective sample.

In example 36, the subject matter of example 35 may include, wherein the input optical beams emanating from the one or more collimating and/or guiding elements are not parallel to one another.

In example 37, the subject matter of any one or more of examples 32 to 36 may include, wherein the method further includes using an objective to form an image of the test area of the sample illuminated by the intermediate optical beams.

In example 38, the subject matter of any one or more of examples 32 to 37 may include, wherein the method further includes supporting achieving of a desired relative position between a test area of the respective sample and at least one light spot generated by the output optical beams illuminating the test area of the respective sample, using a navigation subsystem.

In example 39, the subject matter of example 32 to 38 may include, wherein the method further includes sampling a portion of each of the input optical beams and measuring one or more properties of the input optical beams to identify malfunctions in performances of the input optical beams, and perform corrections to identified malfunctions, using a monitoring subsystem.

In example 40, the subject matter of example 39 may include, wherein at least one of the properties being measured by the monitoring subsystem comprises variations in intensity/power of the input optical beams to enable correction of measured intensity/power variations malfunctions.

In example 41, the subject matter of any one or more of examples 32 to 41 may include, wherein the method further includes using a separate sample inspection subsystem for measuring physical properties of the test area of the sample by using separate at least one illuminator and at least one optical sensor of the sample inspection subsystem.

In example 42, the subject matter of example 41 may include, wherein the sample inspection subsystem is reversibly detachable from optical paths of the input and output optical beams to allow separate measurement of the same test area by illumination by the light source and use of the detection subsystem and by illumination by the illuminator and use of the at least one optical sensor.

In example 43, the subject matter of any one or more of examples 32 to 42 may include, wherein the sample is simultaneously illuminated by the intermediate optical beams, for simultaneous measuring of the respective sample at two or more different polarizations.

Although the above description discloses a limited number of exemplary embodiments of the invention, these embodiments should not apply any limitation to the scope of the invention, but rather be considered as exemplifications of some of the manners in which the invention can be implemented.

The method and/or processes described herein may be implemented by any one or more software, and/or hardware, element apparatus, device, mechanism, electronic and/or digital computerized system, unit, processing module, device, machine, engine, etc.

The system, module, unit, device etc. or parts thereof, may be programmed to perform particular functions pursuant to computer readable and executable instructions, rules, conditions etc. from programmable hardware and/or software based execution modules that may implement one or more methods or processes disclosed herein, and therefore can, in effect, be considered as disclosing a “special purpose computer” particular to embodiments of each disclosed method/process.

Additionally or alternatively, the methods and/or processes disclosed herein may be implemented as a computer program that may be tangibly or intangibly embodied by a special purpose computer readable signal medium. A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a non-transitory computer or machine-readable storage device and that can communicate, propagate, or transport a program for use by or in connection with apparatuses, systems, platforms, methods, operations and/or processes discussed herein.

The terms “non-transitory computer-readable storage device” and “non-transitory machine-readable storage device” may also include distribution media, intermediate storage media, execution memory of a computer, and any other medium or device capable of storing for later reading by a computer program implementing embodiments of a method disclosed herein. A computer program product can be deployed to be executed on one computer or on multiple computers at one site or distributed across multiple sites and interconnected by one or more communication networks.

The computer readable and executable instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

A module, a device, a mechanism, a unit and or a subsystem may each comprise a machine or machines executable instructions (e.g. commands). A module may be embodied by a circuit or a controller programmed to cause the system to implement the method, process and/or operation as disclosed herein. For example, a module may be implemented as a hardware circuit comprising, e.g., custom very large-scale integration (VLSI) circuits or gate arrays, an Application-specific integrated circuit (ASIC), off-the-shelf semiconductors such as logic chips, transistors, and/or other discrete components. A module may also be implemented in programmable hardware devices such as field programmable gate arrays, programmable array logic, programmable logic devices and/or the like.

In the above disclosure, unless otherwise stated, terms such as “substantially”, “about”, approximately, etc., that specify a condition or relationship characterizing a feature or features of an embodiment of the invention, are to be understood to mean that the condition or characteristic is defined to within tolerances that are acceptable for operation of the embodiment for an application for which it is intended.

It is important to note that the methods/processes and/or systems/devices/subsystems/apparatuses etc., disclosed in the above Specification, are not to be limited strictly to flowcharts and/or diagrams provided in the Drawings. For example, a method may include additional or fewer processes or steps in comparison to what is described in the figures. In addition, embodiments of the method are not necessarily limited to the chronological order as illustrated and described herein.

It is noted that terms such as “processing”, “computing”, “calculating”, “determining”, “establishing”, “analyzing”, “checking”, “estimating”, “deriving”, “selecting”, “inferring”, identifying “, “detecting” and/or the like, may refer to operation(s) and/or process(es) of a computer, a computing platform, a computing system, or other electronic computing device(s), that manipulate and/or transform data represented as physical (e.g., electronic or optical signal) quantities within the computer's registers and/or memories into other data similarly represented as physical quantities within the computer's registers and/or memories or other information storage medium that may store instructions to perform operations and/or processes.

Terms used in the singular shall also include a plural scope, except where expressly otherwise stated or where the context otherwise requires.

In the description and claims of the present application, each of the verbs, “comprise” “include” and “have”, and conjugates thereof, are used to indicate that the object or objects of the verb are not necessarily a complete listing of components, elements or parts of the subject or subjects of the verb.

Unless otherwise stated, the use of the expression “and/or” between the last two members of a list of options for selection indicates that a selection of one or more of the listed options is appropriate and may be made i.e. enabling all possible combinations of one or more of the specified options. Further, the use of the expression “and/or” may be used interchangeably with the expressions “at least one of the following”, “any one of the following” or “one or more of the following”, followed by a listing of the various options.

It is appreciated that certain features of the invention, which are, for clarity, described in the context of separate embodiments or example, may also be provided in combination in a single embodiment. Conversely, various features of the invention, which are, for brevity, described in the context of a single embodiment, example and/or option, may also be provided separately or in any suitable sub-combination or as suitable in any other described embodiment, example or option of the invention. Certain features described in the context of various embodiments, examples and/or optional implementation are not to be considered essential features of those embodiments, unless the embodiment, example and/or optional implementation is inoperative without those elements.

It is noted that the terms “in some embodiments”, “according to some embodiments”, “according to some embodiments of the invention”, “for example”, “e.g.”, “for instance” and “optionally” may herein be used interchangeably.

The number of elements shown in the Figures should by no means be construed as limiting and is for illustrative purposes only.

It is noted that the terms “operable to” can encompass the meaning of the term “modified or configured to”. In other words, a machine “operable to” perform a task can in some embodiments, embrace a mere capability (e.g., “modified”) to perform the function and, in some other embodiments, a machine that is actually made (e.g., “configured”) to perform the function.

Throughout this application, various embodiments may be presented in and/or relate to a range format. It should be understood that the description in range format is merely for convenience and brevity and should not be construed as an inflexible limitation on the scope of the embodiments. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals there between.

1. An optical system for measuring properties of a sample, the optical system comprising at least:
an optical head comprising at least a polarizing beam splitter (PBS);
an illumination subsystem comprising at least:
a light source,
a light splitting element configured to separate an initial optical beam emanating from said light source into at least two spatially separated non-polarized input optical beams;
a first optical setup comprising one or more optical elements configured at least to direct each of said input optical beams into the PBS;
wherein the PBS is located and configured to polarize the input optical beams to produce at least two polarized intermediate optical beams having different polarization properties, wherein the intermediate optical are directed to illuminate substantially the same area of a sample to be measured,
wherein the PBS is further used to split light returned from the sample, to form at least two polarized output beams, having different polarization properties; and
a detection subsystem having at least one optical detector, configured to separately detect each of the output optical beams, returned from the sample.

2. The optical system of claim 1, wherein the polarized at least two intermediate optical beams and/or at least two output optical beams formed by the PBS have orthogonal polarizations.

3. The optical system of any one of claims 1 to 2, wherein the first optical setup is configured to direct each of the input optical beams onto different input surfaces of the PBS that are angular or perpendicular to one another.

4. The optical system of any one of claims 1 to 3 further comprises at least one additional polarizer.

5. The optical system of any one of claims 1 to 4, wherein the at least two input optical beams have same or similar optical properties.

6. The optical system of any one of claims 1 to 5, wherein the sample is simultaneously illuminated by the intermediate optical beams, for simultaneous measuring of the respective sample at two or more different polarizations.

7. The optical system of any one of claims 1 to 6, wherein the light source is configured to output light of one of the following properties:
white light;
broadband light;
light in the visual (VIS) wavelength (WL) range;
light in the infrared (IR) WL range;
light in the ultraviolet (UV) WL range.

8. The optical system of any one of claims 1 to 7, wherein the first optical setup further comprises one or more of
an illumination relay lens (IRL);
two or more field stops, each positioned along an optical path of a different input optical beam and configured to limit the field of view (FOV) of each of the input optical beams outputted from the light splitting element; and/or
a guiding unit comprising one or more beams collimating and/or guiding elements, for collimating and/or redirecting image of each of the input optical beams while maintaining spatial separation therebetween;
one or more reflective and/or semi-reflective elements for directing each of the input optical beams such as to enter the PBS from a different surface of the PBS.

9. The optical system of claim 8, wherein one or more of the reflective and/or semi-reflective elements of the first optical setup are controllably moveable.

10. The optical system of any one of claims 8 to 9, wherein the first optical setup is further configured to generate at least two spatially separated images of the initial optical beam emanating from the light source.

11. The optical system of claim 10, wherein the guiding unit comprises an illumination tube lens (ITL), configured to collimate and/or redirect image of each of the input optical beams passed through the field stops.

12. The optical system of claim 11, wherein the input optical beams are outputted from a front surface of the ITL such that they are not parallel to one another.

13. The optical system of any one of claims 1 to 12, wherein the detection subsystem comprises:
at least two optical detectors, each configured and/or positioned to detect light of a different polarization property; and
a second optical setup, which uses at least one of the optical elements of the first optical setup and/or additional optical elements, wherein the second optical setup is configured and arranged to direct each output optical beam to a different optical detector.

14. The optical system of claim 13, wherein at least one of the at least two optical detectors comprises a collection optical fiber.

15. The optical system of any one of claims 1 to 14, wherein the optical head further comprises an objective located between a sample handler and the PBS.

16. The optical setup of claim 15, wherein the optical head, the objective, and/or the sample is locatable such that the intermediate optical beams are combined and conjugated by the PBS and the objective to conjugate to a plane of the objective pupil that corresponds to a specific test area or central test area of the sample.

17. The optical system of any one of claims 1 to 16 further comprising a controllable displacement subsystem configured for moving of the optical head, a sample handler, and/or one or more parts of the sample handler.

18. The optical system of any one of claims 1 to 17, wherein the BPS is configured for outputting intermediate and output optical beams of p-polarization and s-polarization.

19. The optical system of any one of claims 1 to 18, wherein the at least one optical detector comprises at least one spectrometer.

20. The optical system of any one of claims 1 to 19 further comprising a monitoring subsystem configured and arranged to sample a portion of each of the input optical beams and measure variations in intensity/power of the input optical beams to enable correction of measured intensity/power variations.

21. The optical system of claim 20, wherein the monitoring subsystem comprises at least one additional detector; and at least one optical element configured and positioned to simultaneously direct a portion from each input optical beam towards the at least one additional detector.

22. The optical system of any one of claims 1 to 21 further comprising a processing unit configured to receive and process data outputted from the at least one optical detector, to determine one or more physical properties of each sample being measured.

23. The optical system of any one of claims 1 to 22, wherein each sample being measured is a semiconductor wafer.

24. The optical system of any one of claims 1 to 23, wherein the illumination subsystem further comprises a single optical fiber for outputting the initial light source to be split by the light splitting element; or two or more optical fibers each connectable to the light source and each being connected and configured to output a different input optical beam.

25. The optical system of any one of claims 1 to 24 further comprising a navigation subsystem configured and arranged to support achieving of a desired relative position between a test area of the respective sample and at least one light spot generated by the output optical beams illuminating the test area of the respective sample.

26. The optical system of one of claims 1 to 25, wherein the first optical setup further comprises two or more shutters each positioned and configured to limit or prevent passage of a corresponding input optical beam.

27. The optical system of any one of claims 1 to 26 further comprising a sample inspection subsystem comprising at least one illuminator, a third optical setup and at least one optical sensor, the sample inspection subsystem being configured and positionable to measure physical properties of at least one test area of the respective sample by directing at least some of the light returned from the respective sample towards the at least one optical sensor.

28. The optical system of claim 27, wherein the sample inspection subsystem comprises a detachment mechanism for detaching from optical paths of the input and output optical beams to allow separate measurement of the same test area by illumination by the light source and use of the detection subsystem and by illumination by the illuminator and use of the at least one optical sensor.

29. The optical system of claim 28, wherein the detachment mechanism comprises a controllably movable reflector.

30. The optical system of any one of claims 27 to 29, wherein the sample inspection subsystem comprises:
a first illuminator;
a second illuminator;
an optical sensor;
a third optical setup comprising optical elements that are positioned and configured to direct light emanating from the first and second illuminators towards the test area of the respective sample and light returned from the test area towards the optical sensor.

31. The optical system of any one of claims 27 to 30, wherein the at least one optical sensor comprises one or more of: a camera, a pixelated optical sensor, a CCD camera, a spectrometer, an array of photo detectors.

32. A method for measuring properties of a sample, the method comprising at least:
providing at least one light source outputting an initial optical beam, which is non-polarized;
splitting the initial optical beam into two or more non-polarized spatially separated input optical beams;
directing each of the input optical beams through a polarizing beam splitter (PBS) for producing at least two polarized intermediate optical beams having different polarization properties, using a first optical setup;
directing the at least two polarized intermediate optical beams such as to illuminate at least one area of a respective sample;
directing light returned from the sample through the same PBS, to form at least two polarized output beams, having different polarization properties; and
separately detecting each of the output optical beams, returned from the sample, using at least one optical detector to determine one or more physical properties of the respective sample.

33. The method of claim 32 further comprising receiving and processing data outputted from the at least one optical detector, using a processing unit and determining one or more physical properties of the respective sample being measured, based on processing of corresponding received data associated with detected returned light from the respective sample.

34. The method of claim 33 further comprising outputting information indicative of determined one or more physical characteristics of the respective sample.

35. The method of any one of claims 32 to 34 further comprising:
directing light from the light source through an illumination relay lens (IRL);
splitting light outputted from the IRL into the two or more non-polarized and spatially separated input optical beams, using the light splitting element;
directing the input optical beams from the to the light splitting element towards two or more field stops, each positioned along an optical path of a different input optical beam and configured to limit the field of view (FOV) of each of the input optical beams emanating from the light splitting element;
collimating and/or guiding each of the input optical beams passed through the field stops while maintaining spatial separation therebetween, using one or more collimation and/or guiding elements; and
directing each of the input optical beams, emanating from the one or more collimating and/or guiding elements, such as to enter the PBS from a different surface of the PBS to form the at least two differently polarized intermediate optical beams further directed towards a test area over the respective sample.

36. The method of claim 35, wherein the input optical beams emanating from the one or more collimating and/or guiding elements are not parallel to one another.

37. The method of one of claims 32 to 36 further comprising using an objective to form an image of the test area of the sample illuminated by the intermediate optical beams.

38. The method of one of claims 32 to 37 further comprising supporting achieving of a desired relative position between a test area of the respective sample and at least one light spot generated by the output optical beams illuminating the test area of the respective sample, using a navigation subsystem.

39. The method of any one of claims 32 to 38 further comprising sampling a portion of each of the input optical beams and measuring one or more properties of the input optical beams to identify malfunctions in performances of the input optical beams, and perform corrections to identified malfunctions, using a monitoring subsystem.

40. The method of claim 39, wherein at least one of the properties being measured by the monitoring subsystem comprises variations in intensity/power of the input optical beams to enable correction of measured intensity/power variations malfunctions.

41. The method of any one of claims 32 to 40 further comprising using a separate sample inspection subsystem for measuring physical properties of the test area of the sample by using separate at least one illuminator and at least one optical sensor of the sample inspection subsystem.

42. The method of claim 41, wherein the sample inspection subsystem is reversibly detachable from optical paths of the input and output optical beams to allow separate measurement of the same test area by illumination by the light source and use of the detection subsystem and by illumination by the illuminator and use of the at least one optical sensor.

43. The method of any one of claims 32 to 42, wherein the sample is simultaneously illuminated by the intermediate optical beams, for simultaneous measuring of the respective sample at two or more different polarizations.
